(19) United States
(12) Patent Application Publication
(10) Pub. No.: US 2023/0152866 A1
(43) Pub. Date: May 18, 2023

(54) SYSTEMS AND METHODS FOR USE OF MAGNETS TO RETAIN AND EJECT COMPUTING DEVICE EXPANSION MODULES

(71) Applicant: Lenovo Global Technology (United States) Inc., Morrisville, NC (US)

(72) Inventors: John Michael Petersen, Morrisville, NC (US); Gary David Cudak, Morrisville, NC (US); Nathan J. Peterson, Morrisville, NC (US); Jarrod B. Johnson, Morrisville, NC (US)

(21) Appl. No.: 17/524,829

(22) Filed: Nov. 12, 2021

(51) Int. Cl. G06F 1/18; H05K 7/14

(52) U.S. Cl. CPC G06F 1/183; H05K 7/1401

(57) ABSTRACT

Systems and methods for use of magnets to retain and eject computing device expansion modules are disclosed. According to an aspect, a system includes a computing device that defines a slot for receipt of an expansion module for operable positioning of the expansion module with respect to the computing device. The expansion module comprises a first magnet attached thereto. Further, the system includes an electromagnet attached to the slot of the computing device. The system also includes a controller configured to apply an electrical output to the electromagnet such that the electromagnet generates a magnetic field for repelling the first magnet such the expansion module is urged in a direction for ejection from the slot.

### TECHNICAL FIELD

The presently disclosed subject matter relates generally to expansion modules of computing devices. Particularly, the presently disclosed subject matter relates to systems and methods for use of magnets to retain and eject computing device expansion modules.

### BACKGROUND

Servers are computers that provide functionality for other computing devices, referred to as clients. For example, a server can provide functionality such as computing resources among multiple clients and also access to stored data. Various types of servers include, application servers, database servers, file servers, email servers, and web servers. Server centers or clusters are collections of servers. Due to their important functions, there is a desire to optimize the performance of servers and to reduce the impact of component failures on performance.

Servers typically include multiple lights or other indicators to indicate their operations and performance. Such lights may indicate the operation or need for maintenance on the server's drives. This maintenance light can be difficult to find among multiple racks of servers at a server center. In addition, the maintenance light can be very difficult to distinguish from another light, such as an activity light, for those with colorblindness. These drives requiring maintenance and their associated lights will continue to consume power when plugged in. In view of these difficulties, there is a need for improved systems and techniques for indicating a need for drive maintenance.

### BRIEF DESCRIPTION OF THE DRAWINGS

Having thus described the presently disclosed subject matter in general terms, reference will now be made to the accompanying Drawings, which are not necessarily drawn to scale, and wherein:

FIG. 1A is a schematic diagram of a system including a computing device with an expansion module operably positioned in a slot thereof in accordance with embodiments of the present disclosure;

FIG. 1B is a schematic diagram of the system of FIG. 1A with the expansion module partially within the slot;

FIG. 2 is a flow diagram of a method for controlling retention and ejection of an expansion module of a computing device in accordance with embodiments of the present disclosure;

FIG. 3 is a bottom view of an expansion module in an operable position with respect to electropermanent magnets for retention and for ejection, respectively, in accordance with embodiments of the present disclosure; and

FIG. 4 is a bottom view of an expansion module with the permanent magnet in an alternative position as shown in FIG. 3 in accordance with embodiments of the present disclosure.

### SUMMARY

The presently disclosed subject matter relates to systems and methods for use of magnets to retain and eject computing device expansion modules. According to an aspect, a system includes a computing device that defines a slot for receipt of an expansion module for operable positioning of the expansion module with respect to the computing device. The expansion module comprises a first magnet attached thereto. Further, the system includes an electromagnet attached to the slot of the computing device. The system also includes a controller configured to apply an electrical output to the electro magnet such that the electromagnet generates a magnetic field for repelling the first magnet such the expansion module is urged in a direction for ejection from the slot.

According to another aspect, a system includes a computing device that defines a slot for receipt of an expansion module for operable positioning of the expansion module with respect to the computing device. The expansion module comprises a first magnet attached thereto. Further, the system includes an electromagnet attached to the slot of the computing device. The system also includes a controller configured to apply an electrical output to the electromagnet such that the electromagnet generates a magnetic field for attracting the first magnet such the expansion module is urged in a direction for retention of the expansion module in the slot.

### DETAILED DESCRIPTION

The following detailed description is made with reference to the figures. Exemplary embodiments are described to illustrate the disclosure, not to limit its scope, which is defined by the claims. Those of ordinary skill in the art will recognize a number of equivalent variations in the description that follows.

Articles “a” and “an” are used herein to refer to one or to more than one (i.e. at least one) of the grammatical object of the article. By way of example, “an element” means at least one element and can include more than one element.

“About” is used to provide flexibility to a numerical endpoint by providing that a given value may be “slightly above” or “slightly below” the endpoint without affecting the desired result.

The use herein of the terms “including,” “comprising,” or “having,” and variations thereof is meant to encompass the elements listed thereafter and equivalents thereof as well as additional elements. Embodiments recited as “including,” “comprising,” or “having” certain elements are also contemplated as “consisting essentially of” and “consisting” of those certain elements.

As used herein, the term “memory” is generally a storage device of a computing device. Examples include, but are not limited to, read-only memory (ROM) and random access memory (RAM).

As referred to herein, the terms “computing device” and “entities” should be broadly construed and should be understood to be interchangeable. They may include any type of computing device, for example, a server, a desktop computer, a laptop computer, a smart phone, a cell phone, a pager, a personal digital assistant (PDA, e.g., with GPRS NIC), a mobile computer with a smartphone client, or the like.

As referred to herein, an electromagnet is a magnet of a type that generates a magnetic field in response to application of an electric current. In an example, an electromagnet can be a wire wound into a coil. In this example, a current through the wire generates a magnetic field which is concentrated in the hole. When the current is turned off, the electromagnet does not produce a magnetic field. The magnitude of magnetic field generated varies based on the applied electric current.

A particular type of electromagnet is an electropermanent magnet. Several of the embodiments and examples provided herein utilize electropermanent magnets, but it should be understood that alternatively any suitable type of electromagnet may be used. Regarding an electropermanent magnet, the magnetic field can be switched on or off by a pulse of electric current in a wire winding around a portion of the magnet. The electropermanent magnet has two sections: one section of high coercivity magnetic material, and the other section of low coercivity material. The direction of magnetization of the low coercivity material can be switched by a pulse of current in a wire winding about the high coercivity magnetic material. When the two portions have opposing magnetizations, the magnet generates no net external field across its poles, while when their direction of magnetization is aligned the magnet generates an external magnetic field.

Unless otherwise defined, all technical terms used herein have the same meaning as commonly understood by one of ordinary skill in the art to which this disclosure belongs.

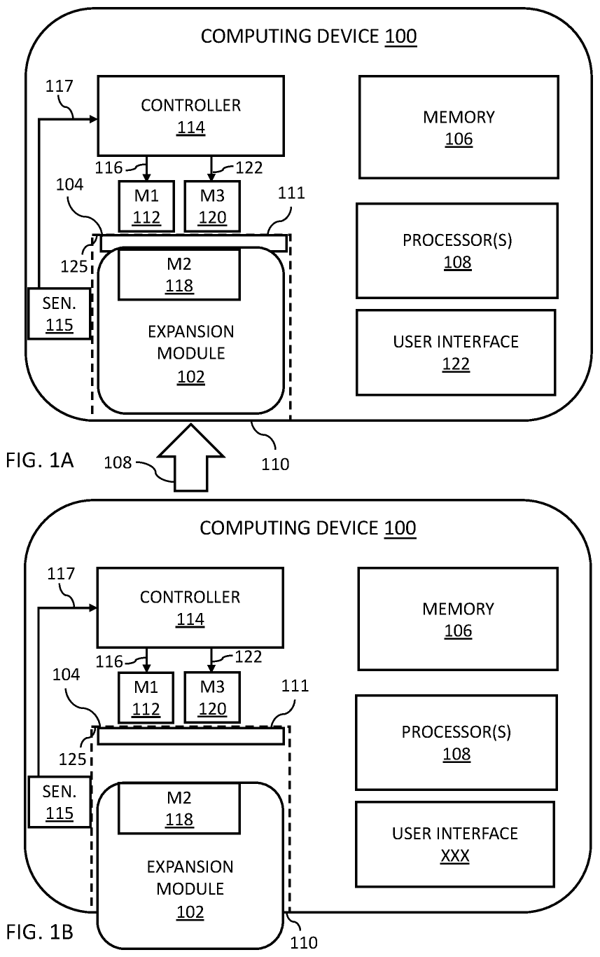

FIG. 1A illustrates a schematic diagram of a system including a computing device 100 with an expansion module 102 operably positioned in a slot 104 thereof in accordance with embodiments of the present disclosure. Referring to FIG. 1A, the computing device 100 can be any electronic device configured to receive and connect to an expansion module for adding to the functionalities of the computing device 100. For example, the computing device 100 can be a server having multiple slots with electronic interfaces for receipt of and connection to expansion modules. In other examples, the computing device 100 can be a desktop computer, a laptop computing, a smartphone, a tablet computer, or any other suitable electronic device. Example expansion modules include, but are not limited to, hard drives, subscriber identification module (SIM) cards, a secure digital (SD) cards, wearable accessories, and the like. An expansion module can provide additional memory, processing, or other specialized functionality to a connected computing device.

The computing device 100 may be implemented in programmable hardware devices such as processors, digital signal processors, central processing units, field programmable gate arrays, programmable array logic, programmable logic devices, cloud processing systems, or the like. In the example of FIG. 1A, the computing device 100 includes memory 106 and one or more processors 108. The memory 106 may contain executable code as software for execution by the processor(s) 108. An executable code of a computing device may be a single instruction, or many instructions, and may even be distributed over several different code segments, among different applications, and across several memory devices. Similarly, operational data may be identified and illustrated herein within the computing device 100, and may be embodied in any suitable form and organized within any suitable type of data structure. The operational data may be collected as a single data set, or may be distributed over different locations including over different storage devices, and may exist, at least partially, as electronic signals on a system or network.

The expansion module 102 may be sized and shaped to fit into the slot 104. The slot 104 may define an opening 110 such that the expansion module 102 may be received into the slot 104 and positioned as shown in FIG. 1A. The expansion module 102 is moved generally in the direction indicated by arrow 108 in order to be received into the slot 104 and positioned as shown. In this position, the expansion module 102 is operably connected to the computing device. Particularly, the expansion module 102 is operably connected to a socket or other electrical connector 111 of the computing device such that the circuitry of the expansion module 102 can function with the computing device 100 via the socket 111 as will be understood by those of skill in the art. Further, the computing device 100 can include mechanisms for receiving and supporting the expansion module 102 within the slot 104 in the position shown in FIG. 1A.

The computing device 100 includes an electropermanent magnet M1 112 that is operably connected to a controller 114. The controller 114 can be electrically connected to the electropermanent magnet M1 112 and operable to controllably apply electrical pulses to the electropermanent magnet M1 112. An external magnetic field of the electropermanent magnet M1 112 can be modulated in response to the application of electrical pulses. In this example, the controller 114 can apply electrical pulses to the electropermanent magnet M1 112 for switching on or off the electropermanent magnet M1 112. As described in further detail, the switch control of the electropermanent magnet M1 112 can be used for ejecting the expansion module 102 from the slot 104. Also, it is noted that the magnet M1 112 may in general be any suitable electromagnet or multiple electromagnets that are suitably operated for implementing the functionalities described herein.

During operation to eject the expansion module 102, the controller 114 can apply an electrical signal via line 116 to switch on the electropermanent magnet M1 112. As a result of applying the electrical signal, the electropermanent magnet M1 112 generates a magnetic field that influences a nearby magnet M2 118, which is attached to the expansion module 102. In this example, magnet M2 118 is a permanent magnet aligned such that one of its poles points substantially towards magnet M1 112. The like pole of magnet M1 112 points towards magnet M2 118 such that the magnet repel each other when magnet M1 112 is switched on. The repelling force is sufficiently strong such that the expansion module 102 is moved in a direction that opposes the direction of arrow 108 and thereby released from its connection to the socket 111. This generated repelling force causes removal of the expansion module 102 from the operable position. In this manner, the controller 114 can control ejection of the expansion module 102 by application of a suitable electrical signal to magnet M1 112 when the expansion module 102 is in the operable position as shown in FIG. 1A.

It is noted that in order to receive the expansion module 102 in the operable position, the controller 114 can switch off the magnet M1 112 so that the magnet M1 112 does not repel the magnet M2 118 of the expansion module. In an example, the computing device 100 may be configured with a sensor 115 or otherwise to detect a condition that an expansion module is not within the slot 104. In response to detection of this condition, the controller 114 may apply an electrical signal to the magnet M1 112 to switch it off.

The sensor 115 may be electrically connected to the controller 114 via line 117. The sensor 115 may detect a position of the expansion module 102 within the slot 104 and whether an expansion module is within the slot 104. For example, the sensor 115 may detect that the expansion module is in the operable position as shown in FIG. 1A. Also, for example, the sensor 115 can detect that the expansion module 102 is not in the operable position. The sensor 115 can output an electrical signal to the controller 114 to indicate the position of the expansion module 102 and whether an expansion module 102 is positioned within the slot 104.

FIG. 1B illustrates a schematic diagram of the system of FIG. 1A with the expansion module 102 partially within the slot 104. Referring to FIG. 1B, the expansion module 102 can be in this position prior to connection to the socket 111 in the operable position, or subsequent to ejection when the expansion module 102 is being removed from the computing device 102.

Within continuing reference to FIGS. 1A and 1B, the computing device 102 can include another electropermanent magnet M3 120 that is operably connected to the controller 114 via line 122. The controller 114 is operable to controllably apply electrical pulses to the electropermanent magnet M3 120. An external magnetic field of the electropermanent magnet M2 120 can be modulated in response to the application of electrical pulses. In this example, the controller 114 can apply electrical pulses to the electropermanent magnet M3 120 for switching on or off the electropermanent magnet M3 120. As described in further detail, the switch control of the electropermanent magnet M3 120 can be used for holding the expansion module 102 in operable position as shown in FIG. 1A and for holding the expansion module 102 in the operable position shown in FIG. 1A.

During operation to hold the expansion module 102 in the operable position, the controller 114 can apply an electrical signal via line 122 to switch on the electropermanent magnet M3 120. As a result of applying the electrical signal, the electropermanent magnet M3 120 generates a magnetic field that influences the magnet M2 118 of the expansion module 102. In this example, the poles of magnet M2 118 and magnet M3 120 are in substantially the same direction. As a result, the magnets M1 and M2 (118 and 120, respectively) are attracted to each other when magnet M3 120 is switched on. The attraction is sufficiently strong such that the expansion module 102 is retained in the operable position. This attraction force retains the expansion module 102 in the operable position and can also cause the expansion module 102 to be pulled or inserted into the operable position. In this manner, the controller 114 can control retention of the expansion module 102 by application of a suitable electrical signal to magnet M3 120 when the expansion module 102 is in the operable position as shown in FIG. 1A.

It is noted that prior to ejection of the expansion module by switching on magnet M1 112, the magnet M3 120 may be turned off so that the repelling and attraction forces do not oppose one another at the same time. Further, when there is no expansion module 102 within the slot 104, both magnet M1 and M3 may be switched off.

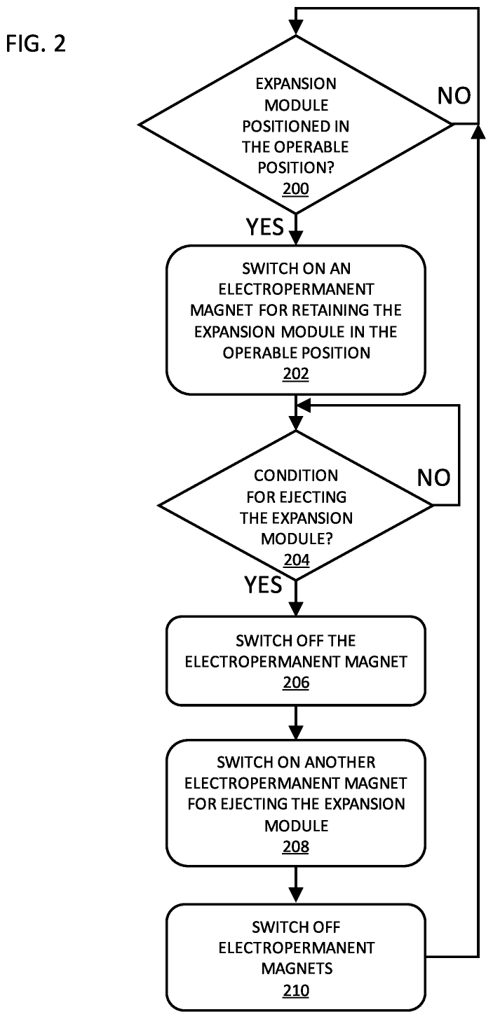

Further, although the magnets M1, M2, and M3 are shown singly in the examples of FIGS. 1A and 2B, it should be appreciated that they may alternatively be two or more magnets configured to implement the functions described for the individual magnets M1, M2, and M3. For example, magnet M2 118 may be two magnets arranged for ejection and retention operations with magnets M1 112 and M3 120, respectively, as described herein.

The controller 114 may include hardware, software, firmware or combinations thereof for implementing the functions described herein. For example, the controller 114 may include memory and one or more processors. In an example, the controller 114 may be part of a baseboard management controller (BMC). Alternatively, for example, the controller may be implement in part or entirely by an operating system, a user interface, or the like.

The computing device 100 may include a user interface 122. The user interface may be a display, a light emitting diode (LED) or other type of light, or the like for indicating a state or an operation of the controller 114. For example, the controller 114 may be communicatively connected to the user interface 122 and configured to signal to the user interface 122 one or more of the following: a position of an expansion module, whether an expansion module is in the operable position, whether the expansion module is being retained, whether the expansion module is being ejected, and any other states or operations described herein. The user interface 122 may in turn present the state or operation of the controller 114.

FIG. 2 illustrates a flow diagram of a method for controlling retention and ejection of an expansion module of a computing device in accordance with embodiments of the present disclosure. The method is described by example as being implemented by the system shown in FIGS. 1A and 1B, although it should be understood that the method may alternatively be implemented by any other suitable system having a computing device and magnets in accordance with examples described herein.

Referring to FIG. 2, the method includes determining 200 that an expansion module is positioned in the operable position or that there is not an expansion module in the operable position. For example, the sensor 115 shown in FIGS. 1A and 1B can detect an indication of whether the expansion module 102 is positioned within the slot 104 in its operable position. Further, the sensor 115 may output a signal to the controller 114 to indicate that the expansion module 102 is positioned within the slot 104. Conversely, the sensor 115 can provide an indication that there is no expansion module in the operable position. The controller 114 can receive indication of either an expansion module is in the operable position or not for making the determination. In response to determining that there is no expansion module in the operable position, the controller 114 continue to monitor the condition. In response to determining that there is an expansion module in the operable position, the method may proceed to step 202.

At step 202, the method includes switching on an electropermanent magnet for retaining the expansion module in the operable position. Continuing the aforementioned example, the controller 114 can apply an electrical signal via line 116 to switch on the electropermanent magnet M1 112. As described herein, this causes electropermanent magnet M1 112 generates a magnetic field to attract magnet M2 118 of the expansion module 102 to hold the expansion module 102 in the operable position. The electropermanent magnet may be maintained as switched on while the expansion module is functioning with the computing device to which it is connected.

Subsequently, the method includes determining 204 a condition for ejecting the expansion module. Continuing the aforementioned example, the controller 114 can determine a condition for ejecting the expansion module 102. For example, a user of the computing device 100 may enter a command for ejecting the expansion module 102, or a process running on the computing device 100 may determine to eject the expansion module 102 and suitably notify the controller 114. For example, it may be determined that the expansion module 102 is defective, inoperable, or in need of maintenance. In this instance, the expansion module 102 may be ejected. In response to determining that the expansion module is not to be ejected, the controller 114 can continue to maintain the electropermanent magnet as switched on. In response to determining that the expansion module is to be ejected, the method may proceed to step 206.

At step 206, the method includes switching off the electropermanent magnet to release the expansion module. Continuing the aforementioned example, the the controller 114 can switch off the magnet M1 112 so that the expansion module 102.

At step 208, the method includes switching on another electropermanent magnet for ejecting the expansion module. Continuing the aforementioned example, the controller 114 can apply an electrical pulse to electropermanent magnet M3 120 for ejecting the expansion module 102 as described herein. Subsequent to ejection, the expansion module 102 may be positioned outside of the operable position such as in the position shown in FIG. 1B. In the position shown in FIG. 1B, a portion of the expansion module 102 is outside of the computing device 100 such that an operator can see that it has been ejected. At step 210, both electromagnet magnets may be switched off.

Subsequent to ejecting the expansion module, the method may return to step 200 to continue monitoring whether an expansion module is in the operable position at step 200. For example, an operator may return the expansion module 102 to the operable position and the return to the operable position is detected. Alternatively, another expansion module is placed in the operable position, and this may be detected.

It is noted that when an expansion module is partially outside of the computing device, an operator may recognize it may be in need of maintenance or replacement. Particularly for example, the controller 114 may be notified or otherwise determine that the expansion module 102 is in need of maintenance or replacement. In response to this determination, the controller 114 may release the expansion module and eject it as described herein. As an example, the expansion module 102 may be ejected to be in the position shown in FIG. 1B. In this case, an operator can easily recognize that the expansion module 102 is in need of maintenance or replacement due to it having been ejected.

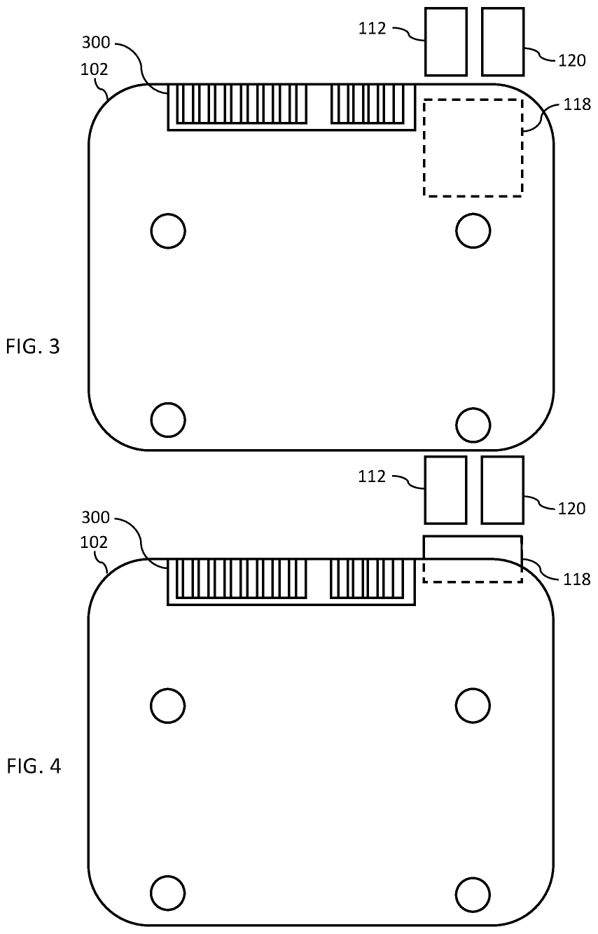

FIG. 3 illustrates a bottom view of an expansion module 102 in an operable position with respect to electropermanent magnets 112 and 120 for retention and for ejection, respectively, in accordance with embodiments of the present disclosure. Referring to FIG. 3, the expansion module 102 includes the permanent magnet 118, which is positioned and arranged with magnets 112 and 120 for functionality in accordance with the examples described herein. More particularly, here the expansion module 102 is positioned in the operable position with respect to magnets 112 and 120. It is noted that only electropermanent magnets 112 and 120 of the computing device 100 are shown for simplicity of illustration.

The permanent magnet 118 is depicted with broken lines because it is contained and held within the housing of the expansion module. Also, it is arranged nearby the socket interface 300 of the expansion module 102. The space between permanent magnet 118 and the socket interface 300 may be suitably shielded as needed to avoid magnetic interference by the magnet 118.

The magnet 118 of the expansion module 102 may be in any suitable position or arrangement with respect to the other components of the expansion module. For example, FIG. 4 illustrates a bottom view of an expansion module 102 with the permanent magnet 118 in an alternative position as shown in FIG. 3 in accordance with embodiments of the present disclosure. Referring to FIG. 4, the permanent magnet 118 partially extends from the housing of the expansion module 102. Alternatively, the permanent magnet 118 may entirely extend from the housing or otherwise be suitably arranged for functionality with the magnets of the computing device as described herein.

Returning again to FIGS. 1A and 1B, it is noted that the computing device 100 can include a backplane, generally indicated by reference number 125, that abuts an interface of the expansion module 102. For example, the backplane may abut the socket interface 300 shown in FIG. 3. This may occur when the expansion module 102 is in the operable position within the slot 110 as shown in FIG. 1A. Further, the electropermanent magnets M1 and M3 (112 and 120, respectively) may be attached to the backplane 125.

Further, as will be appreciated by those of skill in the art, the computing device 100 can include a chassis attached to the slot 110. The location of the chassis may generally be indicated by the broken lines shown in FIGS. 1A and 1B. The electropermanent magnets can be attached to the chassis.

In accordance with embodiments, the controller 114 can determine whether the expansion module is ejected. Further, the controller 114 can prevent application of the electrical output to the electropermanent magnet in response to determining that the expansion module is ejected.

The described features, structures, or characteristics may be combined in any suitable manner in one or more embodiments. In the following description, numerous specific details are provided, to provide a thorough understanding of embodiments of the disclosed subject matter. One skilled in the relevant art will recognize, however, that the disclosed subject matter can be practiced without one or more of the specific details, or with other methods, components, materials, etc. In other instances, well-known structures, materials, or operations are not shown or described in detail to avoid obscuring aspects of the disclosed subject matter.

The device or system for performing one or more operations on a memory of a computing device may be a software, hardware, firmware, or combination of these. The device or the system is further intended to include or otherwise cover all software or computer programs capable of performing the various heretofore-disclosed determinations, calculations, or the like for the disclosed purposes. For example, exemplary embodiments are intended to cover all software or computer programs capable of enabling processors to implement the disclosed processes. Exemplary embodiments are also intended to cover any and all currently known, related art or later developed non-transitory recording or storage mediums (such as a CD-ROM, DVD-ROM, hard drive, RAM, ROM, floppy disc, magnetic tape cassette, etc.) that record or store such software or computer programs. Exemplary embodiments are further intended to cover such software, computer programs, systems and/or processes provided through any other currently known, related art, or later developed medium (such as transitory mediums, carrier waves, etc.), usable for implementing the exemplary operations disclosed below.

In accordance with the exemplary embodiments, the disclosed computer programs can be executed in many exemplary ways, such as an application that is resident in the memory of a device or as a hosted application that is being executed on a server and communicating with the device application or browser via a number of standard protocols, such as TCP/IP, HTTP, XML, SOAP, REST, JSON and other sufficient protocols. The disclosed computer programs can be written in exemplary programming languages that execute from memory on the device or from a hosted server, such as BASIC, COBOL, C, C++, Java, Pascal, or scripting languages such as JavaScript, Python, Ruby, PHP, Perl, or other suitable programming languages.

The present subject matter may be a system, a method, and/or a computer program product. The computer program product may include a computer readable storage medium (or media) having computer readable program instructions thereon for causing a processor to carry out aspects of the present subject matter.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a RAM, a ROM, an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network, or Near Field Communication. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present subject matter may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++, Javascript or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present subject matter.

Aspects of the present subject matter are described herein with reference to flowchart illustrations and/or block diagrams of methods, apparatus (systems), and computer program products according to embodiments of the subject matter. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present subject matter. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the embodiments have been described in connection with the various embodiments of the various figures, it is to be understood that other similar embodiments may be used, or modifications and additions may be made to the described embodiment for performing the same function without deviating therefrom. Therefore, the disclosed embodiments should not be limited to any single embodiment, but rather should be construed in breadth and scope in accordance with the appended claims.

1. A system comprising:
a computing device that defines a slot for receipt of an expansion module for operable positioning of the expansion module with respect to the computing device, wherein the expansion module comprises a first magnet attached thereto;
an electromagnet attached to the slot of the computing device; and
a controller configured to apply an electrical output to the electromagnet such that the electromagnet generates a magnetic field for repelling the first magnet such the expansion module is urged in a direction for ejection from the slot.

2. The system of claim 1, wherein the expansion module comprises one of a hard drive, a subscriber identification module (SIM) card, a secure digital (SD) card, and a wearable accessory.

3. The system of claim 1, wherein the first magnet is a permanent magnet.

4. The system of claim 1, wherein the controller comprises one of a baseboard management controller, an operating system, and a user interface.

5. The system of claim 1, wherein the computing device comprises a backplane that abuts an interface of the expansion module when the expansion module is in the operable position within the slot, wherein the electromagnet is attached to the backplane.

6. The system of claim 5, wherein the expansion module operably interfaces with an electrical connector of the backplane when in the operable position within the slot.

7. The system of claim 1, wherein the computing device comprises a chassis attached to the slot, wherein the electromagnet is attached to the chassis, and wherein the first magnet is positioned adjacent to the electromagnet when the expansion module is in the operable position within the slot.

8. The system of claim 1, wherein the controller is configured to:
determine a condition needed for ejecting the expansion module; and
apply the electrical output to the electromagnet in response to determining the condition.

9. The system of claim 8, wherein the condition comprises one of a failure of the expansion module, a maintenance state of the expansion module, and a user command to eject the expansion module.

10. The system of claim 1, wherein the controller is configured to:
determine whether the expansion module is ejected; and
prevent application of the electrical output to the electromagnet in response to determining that the expansion module is ejected.

11. A system comprising:
a computing device that defines a slot for receipt of an expansion module for operable positioning of the expansion module with respect to the computing device, wherein the expansion module comprises a first magnet attached thereto;
an electromagnet attached to the slot of the computing device; and
a controller configured to apply an electrical output to the electromagnet such that the electromagnet generates a magnetic field for attracting the first magnet such the expansion module is urged in a direction for retention of the expansion module in the slot.

12. The system of claim 11, wherein the expansion module comprises one of a hard drive, a subscriber identification module (SIM) card, a secure digital (SD) card, and a wearable accessory.

13. The system of claim 11, wherein the first magnet is a permanent magnet.

14. The system of claim 11, wherein the controller comprises one of a baseboard management controller, an operating system, and a user interface.

15. The system of claim 11, wherein the computing device comprises a backplane that abuts an interface of the expansion module when the expansion module is in the operable position within the slot, wherein the electromagnet is attached to the backplane.

16. The system of claim 15, wherein the expansion module operably interfaces with an electrical connector of the backplane when in the operable position within the slot.

17. The system of claim 11, wherein the computing device comprises a chassis attached to the slot, wherein the electromagnet is attached to the chassis, and wherein the first magnet is positioned adjacent to the electromagnet when the expansion module is in the operable position within the slot.

18. The system of claim 11, wherein the controller is configured to:
determine a condition needed for holding the expansion module in the operable position within the slot; and
apply the electrical output to the electromagnet in response to determining the condition.

19. The system of claim 18, wherein the condition is the expansion module being in the operable position.

20. The system of claim 11, wherein the controller is configured to:
determine a condition needed for ejecting the expansion module; and
prevent application of the electrical output to the electromagnet in response to determining the condition.
